(19) United States
(12) Patent Application Publication
(10) Pub. No.: US 2008/0160217 A1
(43) Pub. Date: Jul. 3, 2008

(54) Pulsed Laser Deposition Method

(75) Inventor: Jari Ruuttu, Billnas (FI)

Correspondence Address: YOUNG & THOMPSON, 209 Madison Street, Suite 500, ALEXANDRIA, VA, 22314, US

(73) Assignee: PINTAVISION OY, Helsinki (FI)

(21) Appl. No.: 11/884,835

(22) PCT Filed: Feb. 23, 2006
(86) PCT No.: PCT/FI2006/000069

§ 371 Date: Sep. 13, 2007

(30) Foreign Application Priority Data
Feb. 23, 2005 (FI) 20050216
May 26, 2005 (FI) 20050558
May 26, 2005 (FI) 20050559

(51) Int. Cl. C23C 14/28

(52) U.S. Cl. 427/596

(57) ABSTRACT

The invention relates to a method for coating the plastic casing and/or lens of a portable electronic device, in which the plastic casing and/or lens is coated by laser ablation with the plastic casing and/or lens shifted in a material plasma fan ablated from a moving target in order to achieve a coating having as regular quality as possible. The invention also relates to the product produced by the method.

### FIELD OF THE INVENTION

This invention relates to a method for laser ablation deposition (PLD-Pulsed Laser Deposition), and to a product aiming at producing an optimal surface quality by ablation of a moving target with in order to coat a moving substrate.

### STATE OF THE ART

The laser technology has made considerable progress over the recent years, and nowadays laser systems based on semi-conductor fibres can be produced with tolerable efficiency for use in cold ablation, for instance. Such lasers intended for cold ablation include pico-second lasers and phemto-second lasers. In terms of pico-second lasers, for instance, the cold-ablation range implies pulse lengths having a duration of 100 pico-seconds or less. Pico-second lasers differ from phemto-second lasers both with respect to their pulse duration and to their repetition frequency, the most recent commercial pico-second lasers having repetition frequencies in the range 1-4 MHz, whereas phemto-second lasers operate at repetition frequencies measured only in kilohertz. In the optimal case, cold ablation enables ablation of the material without the ablated material proper being subject to thermal transfers, in other words, the material ablated by each pulse is subject to pulse energy alone.

Besides a fibre-based diode-pumped semi-conductor laser, there are competitive lamp-pumped laser sources, in which the laser beam is first directed to a fibre and from there to the work site. According to the applicant's information by the priority date of the present application, these fibre-based laser systems are presently the only means of providing products based on laser ablation on any industrial scale.

The fibres of current fibre lasers and the consequently restrained beam effect set limits to the choice of materials that can be ablated. Aluminium can be ablated with a reasonable pulse effect as such, whereas materials less apt to ablation, such as copper, tungsten etc., require an appreciably higher pulse effect.

A second prior art feature comprises the scanning width of the laser beam. Linear scanning has been generally used in mirror film scanners, typically yielding a scanning line width in the range 30 mm-70 mm.

To the applicant's knowledge, the efficiency of known pulse-laser devices for cold ablation was only of the order of 10 W by the priority date of the present application. In this case, a pico-second laser achieves pulsing frequencies of about 4 MHz. However, a second pulse laser for cold ablation achieves pulse frequencies measured in kilohertz alone, their operating speed being lower than that of pico-second lasers in various cutting applications, for instance.

The successful use of cold-ablation lasers especially in coating applications always requires high vacuum values, typically of at least 10⁻⁶ atmospheres. The larger the amount of material in the gaseous phase, the weaker and poorer the quality of the material plasma fan formed of the material ablated from the substrate. With an adequate vacuum level, such a material plasma fan will have a height of about 30 mm-70 mm, cf. U.S. Pat. No. 6,372,103.

### SUMMARY OF THE INVENTION

This invention relates to a method for coating the plastic casing and/or lens of a portable electronic device, in which the plastic casing and/or the lens is coated by laser ablation, with the plastic casing and/or the lens shifted in a material plasma fan ablated from a moving target in order to produce a surface having as regular quality as possible.

The invention also relates to the plastic casing and/or lens of a portable electronic device that has been coated by laser ablation with the plastic casing and/or its lens shifted in a material plasma fan ablated from a moving target in order to produce a surface having as regular quality as possible.

The present invention is based on the surprising observation that the surfaces of the plastic casing and/or lens of a portable electronic device can be coated with regular quality if the object (substrate) to be coated is shifted in the material plasma fan ablated from the moving target. The invention enables the deposition of DLC coatings, metal coatings and metal oxide coatings on such bodies by using laser ablation.

### FIGURES

FIG. 1 illustrates the effect of hot ablation and cold ablation on the material to be ablated

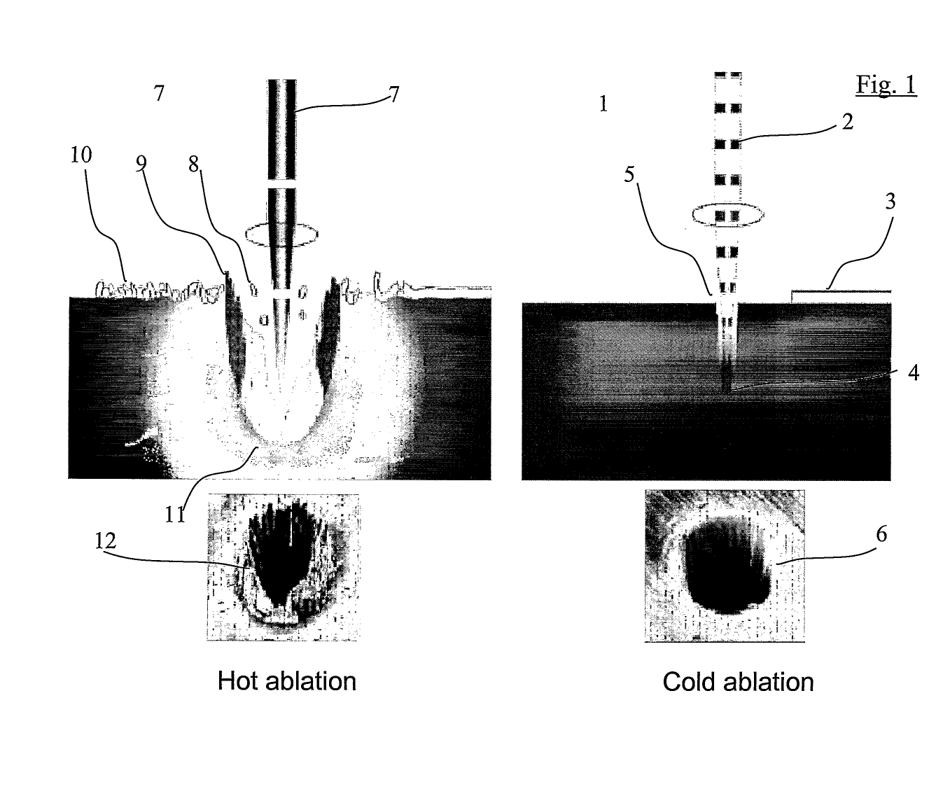

FIG. 2 illustrates a material plasma fan produced in accordance with the invention

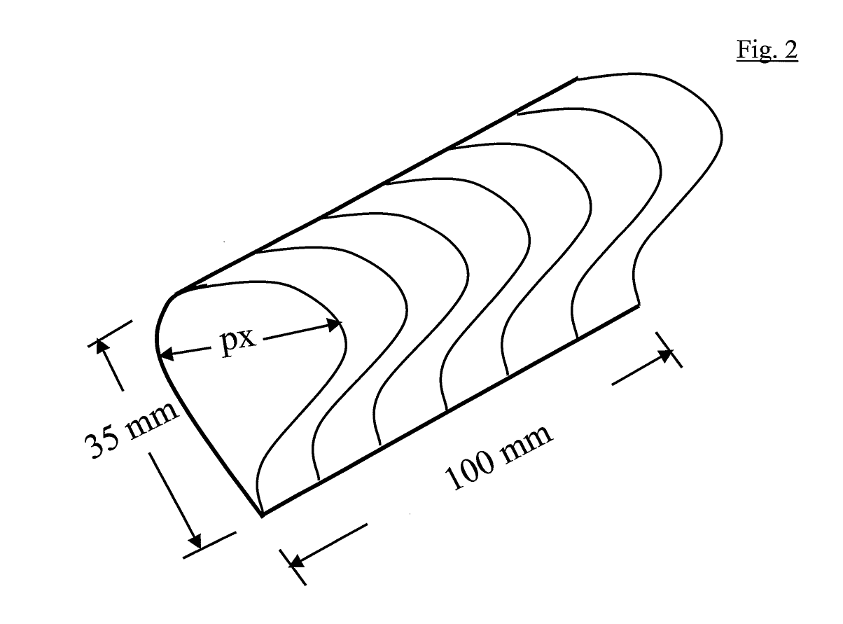

FIG. 3 illustrates the coating method of the invention. The figure illustrates the direction of movement (16) of the body (substrate) to be coated relative to the material plasma fan (17). The distance between the body to be coated and the target (material to be ablated) is 70 mm, and the angle of incidence of the laser beam on the target material body is oblique.

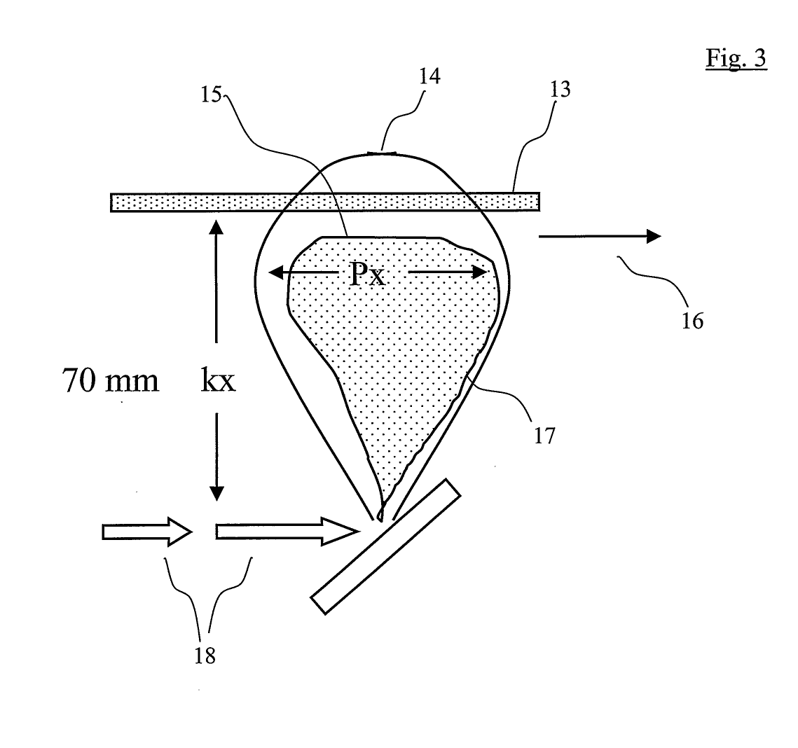

FIG. 4 illustrates the display shields of a portable electronic device that have been coated In accordance with the invention

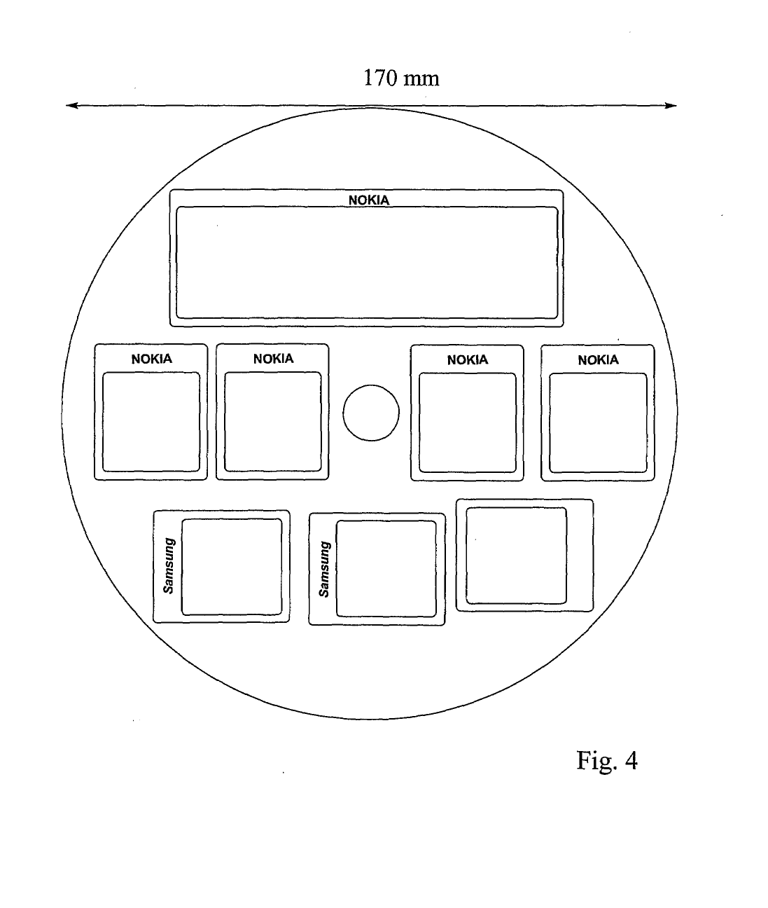

FIG. 5 illustrates a casing solution of a portable electronic device coated in accordance with the invention

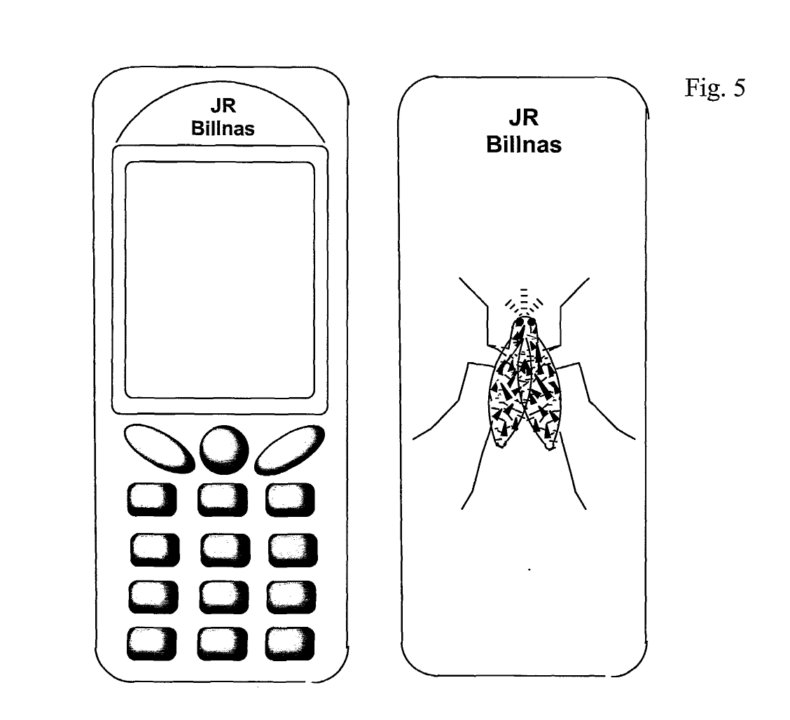

### DETAILED DESCRIPTION OF THE INVENTION

The invention relates to a method for coating the plastic casing and/or lens of a portable electronic device, in which the plastic casing and/or lens is coated by laser ablation with the plastic casing and/or the lens shifted in the material plasma fan ablated from the moving target in order to produce a surface having as regular quality as possible.

In this context, a plastic casing of an electronic device denotes more widely the casings of portable devices for mobile communication, game consoles, positioning means and other portable telecommunication devices. The plastic lenses of these denote any planar display shields for such devices, such as e.g. the plastic lenses of the camera in a camera mobile phone.

In a particularly preferred embodiment of the invention, coating is performed by means of laser ablation with a pulsed laser. The laser apparatus used for such laser ablation preferably comprises a cold-ablation laser, such as a pico-second laser.

The apparatus may also comprise a phemto-second laser, however, a pico-second laser is more advantageously used for coating.

The coating is preferably carried out under a vacuum of 10⁻⁶-10⁻¹² atmospheres.

In a preferred embodiment of the invention, the coating is performed by passing the plastic casing and/or lens to be coated by two or more material plasma fans in succession. This increases the coating speed and yields a coating process more fit for industrial application. The typical distance between the structure to be coated and the target is 30 mm-100 mm, preferably 35 mm-50 mm.

In a particularly advantageous embodiment of the invention, the distance between the target and the structure to be coated is maintained substantially constant over the entire ablation period.

Particularly preferred target materials include graphite, sintered carbons, metals, metal oxides and polysiloxane. Ablation of graphite or carbon allows for the production of diamond-like carbon (DLC) coatings or a diamond coating having a higher sp3/sp2 ratio.

If the target material is a metal, the metal is preferably aluminium, titanium, copper, zinc, chromium, zirconium or tin.

If it is desirable to produce a metal oxide coating, this can be done by direct ablation of metal oxide. In a second embodiment of the invention, a metal oxide coating can be produced by ablating metal in a gas atmosphere containing oxygen. The oxygen may consist of ordinary oxygen or reactive oxygen. In such an embodiment of the invention, the gas atmosphere consists of oxygen and a rare gas, preferably helium or argon, most advantageously helium.

The invention also relates to the plastic casing and/or lens (referred to as body below) of a portable electronic device, the plastic casing and/or lens having been coated by laser ablation with the plastic casing and/or lens shifted in a material plasma fan ablated from a moving target in order to achieve coating having as regular quality as possible.

Such a body has preferably been coated by performing the laser ablation with a pulsed laser. The laser apparatus used for ablation is then preferably a cold-ablation laser, such as a pico-second laser.

The body of the invention is preferably coated under a vacuum of 10⁻⁶-10⁻¹² atmospheres.

In a further preferred embodiment of the invention, the body is coated by passing the plastic casing and/or lens to be coated by two or more material plasma fans in succession. The typical distance between the structure to be coated and the target is 30 mm-100 mm, preferably 35 mm-50 mm.

In a particularly advantageous embodiment of the invention, the body is coated with the distance between the target and the structure to be coated maintained substantially constant over the entire ablation period. A number of preferred target materials include graphite, sintered carbon, metals, metal oxides and polysiloxane. Preferred metals include aluminium, titanium, copper, zinc, chromium, zirconium or tin.

The body can be coated with an oxide layer also by ablating metal in a gas atmosphere into which oxygen has been introduced. Such a gas atmosphere consists of oxygen and a rare gas, preferably helium or argon, most advantageously helium.

### EXAMPLES

The method and product of the invention are described below without restricting the invention to the given examples. The coatings were produced using both X-lase 10 W pico-second laser made by Corelase Oy and X-lase 10 W pico-second laser made by Corelase Oy. Pulse energy denotes the pulse energy incident on an area of 1 square centimeter, which is focussed on an area of the desired size by means of optics.

### Example 1

In this example, a polycarbonate plate was coated with a diamond coating (of sintered carbon). The laser apparatus had the following performance parameters:

### Power 10 W

Repetition frequency 4 MHz
Pulse energy 2.5 μJ
Pulse duration 20 ps
Distance between the target and the substrate 35 mm
Vacuum level 10⁻⁷

The polycarbonate plate was thus coated with a DLC coating having a thickness of approximately 200 nm.

### Example 2

In this example, a polycarbonate plate was coated with a titanium dioxide coating. The laser apparatus had the following performance parameters:

### Power 10 W

Repetition frequency 4 MHz
Pulse energy 2.5 μJ
Pulse duration 20 ps
Distance between the target and the substrate 40 mm
Vacuum level 10⁻⁸

The polycarbonate plate was thus coated with a titanium dioxide coating having a thickness of approximately 100 nm.

1. A method for coating the plastic casing and/or lens of a portable electronic device, characterised in that the plastic casing and/or the lens are coated by laser ablation with the plastic casing and/or lens shifted in a material plasma fan ablated from a moving target in order to achieve a coating having as regular quality as possible.

2. A method as defined in claim 1, characterised in that the laser ablation is performed using a pulsed laser.

3. A method as defined in claim 2, characterised in that the laser apparatus used for ablation is a cold-ablation laser, such as a pico-second laser.

4. A method as defined in claim 1, characterised in that laser ablation is performed under a vacuum of 10⁻⁶ to 10⁻¹² atmospheres.

5. A method as defined in claim 1, characterised in that the coating is performed by passing the plastic casing and/or lens to be coated by two or more material plasma fans in succession.

6. A method as defined in claim 5, characterised in that the distance between the structure to be coated and the target is in the range 30 mm to 100 mm, preferably 35 mm to 50 mm.

7. A method as defined in claim 1, characterised in that the distance between the target and the structure to be coated is maintained substantially constant over the entire ablation period.

8. A method as defined in claim 1, characterised in that the target material is graphite, sintered carbon, metal, metal oxide or polysiloxane.

9. A method as defined in claim 8, characterised in that the metal is aluminium, titanium, copper, zinc, chromium, zirconium or tin.

10. A method as defined in claim 1, characterised in that an oxide coating is formed on the structure to be coated by introducing oxygen into the gas atmosphere of a vacuum chamber.

11. A method as defined in claim 10, characterised in that the gas atmosphere consists of oxygen and a rare gas, preferably helium or argon, most advantageously helium.

12. A plastic casing and/or lens of a portable electronic device, characterised in that the plastic casing and/or lens is coated by laser ablation with the plastic casing and/or the lens shifted in the material plasma fan ablated from a moving target in order to produce a surface having as regular quality as possible.

13. The plastic casing and/or lens of a portable electronic device as defined in claim 12, characterised in that coating is performed by means of laser ablation with a pulsed laser.

14. The plastic casing and/or lens of a portable electronic device as defined in claim 13, characterised in that the laser apparatus used for laser ablation is a cold-ablation laser, such as a pico-second laser.

15. The plastic casing and/or lens of a portable electronic device as defined in claim 12, characterised in that laser ablation is carried out under a vacuum of 10⁻⁶ to 10⁻¹² atmospheres.

16. The plastic casing and/or lens of a portable electronic device as defined in claim 12, characterised in that coating is performed by passing the plastic casing and/or lens to be coated by two or more material plasma fans in succession.

17. The plastic casing and/or lens of a portable electronic device as defined in claim 6, characterised in that the distance between the structure to be coated and the target is 30 mm to 100 mm, preferably 35 mm to 50 mm.

18. The plastic casing and/or lens of a portable electronic device as defined in claim 12, characterised in that the distance between the target and the structure to be coated is maintained substantially constant over the entire ablation period.

19. The plastic casing and/or lens of a portable electronic device as defined in claim 12, characterised in that the target material is graphite, sintered carbon, metals, metal oxide or polysiloxane.

20. The plastic casing and/or lens of a portable electronic device as defined in claim 9, characterised in that the metal is aluminium, titanium, copper, zinc, chromium, zirconium or tin.

21. The plastic casing and/or lens of a portable electronic device as defined in claim 12, characterised in that a metal oxide coating has been produced on the structure to be coated by introducing oxygen into the gas atmosphere in a vacuum chamber.

22. The plastic casing and/or lens of a portable electronic device as defined in claim 10, characterised in that the gas atmosphere consists of oxygen and a rare gas, preferably helium or argon, most advantageously helium.
